(19) United States
(12) Patent Application Publication
(10) Pub. No.: US 2013/0015511 A1
(43) Pub. Date: Jan. 17, 2013

(54) SEMICONDUCTOR DEVICE AND MANUFACTURING METHOD OF SEMICONDUCTOR DEVICE

(71) Applicants: Toshitaka MIYATA, Kanagawa (JP); Nobutoshi AOKI, Kanagawa (JP)

(72) Inventors: Toshitaka MIYATA, Kanagawa (JP); Nobutoshi AOKI, Kanagawa (JP)

(73) Assignee: Kabushiki Kaisha Toshiba, Tokyo (JP)

(21) Appl. No.: 13/546,322

(22) Filed: Jul. 11, 2012

(30) Foreign Application Priority Data
Jul. 14, 2011 (JP) 2011-155911

(51) Int. Cl. H01L 29/78; H01L 21/336

(52) U.S. Cl. 257/288; 438/303; 257/E29.255; 257/E21.409

(57) ABSTRACT

According to one embodiment, a semiconductor device includes a fin-type semiconductor layer formed on a semiconductor substrate, a source layer connected to one end of the fin-type semiconductor layer, a drain layer connected to the other end of the fin-type semiconductor layer, and a gate electrode that includes a first sub electrode that is arranged on the source layer side of the fin-type semiconductor layer to extend toward the drain layer side on the base side of the fin-type semiconductor layer and has a first work function and a second sub electrode that is arranged on the drain layer side of the fin-type semiconductor layer and has a second work function different from the first work function.

### CROSS-REFERENCE TO RELATED APPLICATIONS

This application is based upon and claims the benefit of priority from Japanese Patent Application No. 2011-155911, filed on Jul. 14, 2011; the entire contents of which are incorporated herein by reference.

### FIELD

Embodiments described herein relate generally to a semiconductor device and a manufacturing method of a semiconductor device.

### BACKGROUND

In field-effect transistors, the potential controllability of a channel region by a gate electrode decreases in accordance with the scaling thereof and therefore short channel effects become significant, which makes it difficult to achieve both a reduction of the short channel effects and an increase of the current driving force.

On the other hand, in fin transistors, because a gate electrode is provided on both sides of the channel region, the potential controllability of the channel region is improved, therefore, the fin transistors are effective in achieving both a reduction of the short channel effects and an increase of the current driving force.

Even in such fin transistors, when a fin is formed on a bulk semiconductor, the base of the fin cannot be sandwiched between the gate electrodes, therefore, the potential controllability on the bulk side of the fin decreases. Thus, punch-through occurs easily on the bulk side of the fin and therefore it has been difficult to reduce the off-leakage current.

### BRIEF DESCRIPTION OF THE DRAWINGS

FIG. 1A is a perspective view illustrating a schematic configuration of a semiconductor device according to a first embodiment, FIG. 1B is a diagram illustrating a potential distribution in a gate length direction of a channel region 7 in FIG. 1A, and FIG. 1C is a diagram illustrating a potential distribution in a gate width direction of the channel region 7 in FIG. 1A;

FIG. 2A is a plan view illustrating a manufacturing method of a semiconductor device according to a second embodiment, FIG. 2B is a cross-sectional view illustrating a configuration cut along line A-A in FIG. 2A, and FIG. 2C is a cross-sectional view illustrating a configuration cut along line B-B in FIG. 2A;

FIG. 3 is a plan view illustrating the manufacturing method of the semiconductor device according to the second embodiment;

FIG. 4A is a plan view illustrating the manufacturing method of the semiconductor device according to the second embodiment and FIG. 4B is a perspective view illustrating a configuration of a portion C in FIG. 4A cut out from the semiconductor device;

FIG. 5A and FIG. 5B are perspective views illustrating the manufacturing method of the semiconductor device according to the second embodiment and FIG. 5C is a cross-sectional view illustrating the manufacturing method of the semiconductor device according to the second embodiment;

FIG. 6A and FIG. 6B are perspective views illustrating the manufacturing method of the semiconductor device according to the second embodiment;

FIG. 7A and FIG. 7B are perspective views illustrating the manufacturing method of the semiconductor device according to the second embodiment;

FIG. 8A and FIG. 8B are perspective views illustrating the manufacturing method of the semiconductor device according to the second embodiment;

FIG. 9 is a perspective view illustrating a schematic configuration of a semiconductor device according to a third embodiment;

FIG. 10A is a plan view illustrating a manufacturing method of a semiconductor device according to a fourth embodiment and FIG. 10B is a perspective view illustrating a configuration of a portion C′ in FIG. 10A cut out from the semiconductor device;

FIG. 11A and FIG. 11B are perspective views illustrating the manufacturing method of the semiconductor device according to the fourth embodiment;

FIG. 12 is a perspective view illustrating the manufacturing method of the semiconductor device according to the fourth embodiment;

FIG. 13 is a perspective view illustrating a manufacturing method of a semiconductor device according to a fifth embodiment; and

FIG. 14 is a perspective view illustrating a manufacturing method of a semiconductor device according to a sixth embodiment.

### DETAILED DESCRIPTION

According a semiconductor device in one embodiment, a fin-type semiconductor layer, a source layer, a drain layer, and a gate electrode are provided. The fin-type semiconductor layer is formed on a semiconductor substrate. The source layer is connected to one end of the fin-type semiconductor layer. The drain layer is connected to the other end of the fin-type semiconductor layer. The gate electrode includes a first sub electrode that is arranged on the source layer side of the fin-type semiconductor layer to extend toward the drain layer side on the base side of the fin-type semiconductor layer and has a first work function and a second sub electrode that is arranged on the drain layer side of the fin-type semiconductor layer and has a second work function different from the first work function.

A semiconductor device and a manufacturing method of the semiconductor device according to the embodiments will be explained below with reference to the drawings. The present invention is not limited to these embodiments.

### First Embodiment

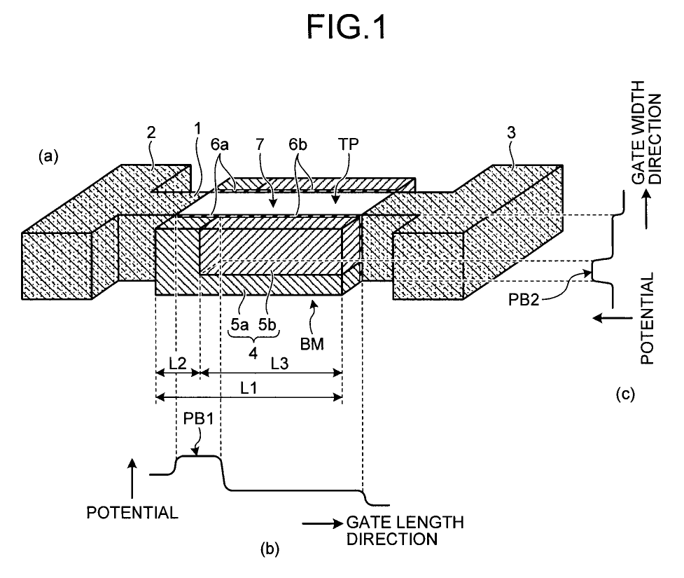

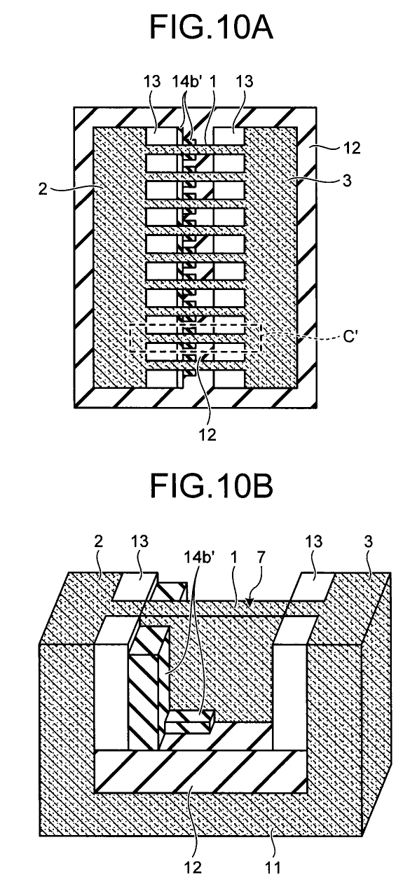

FIG. 1A is a perspective view illustrating a schematic configuration of a semiconductor device according to the first embodiment, FIG. 1B is a diagram illustrating a potential distribution in a gate length direction of a channel region 7 in FIG. 1A, and FIG. 10 is a diagram illustrating a potential distribution in a gate width direction of the channel region 7 in FIG. 1A.

In FIG. 1A to FIG. 10, a fin-type semiconductor layer 1 is formed on a semiconductor substrate and the channel region 7 is formed in the fin-type semiconductor layer 1. A source layer 2 is connected to one end of the fin-type semiconductor layer 1 and a drain layer 3 is connected to the other end of the fin-type semiconductor layer 1. The materials of the semiconductor substrate, the fin-type semiconductor layer 1, the source layer 2, and the drain layer 3 can be selected, for example, from Si, Ge, SiGe, SiC, SiSn, PbS, GaAs, InP, InGaAsP, GaP, GaN, ZnSe, and the like.

A gate electrode 4, which controls the potential of the channel region 7, is arranged on both side surfaces of the fin-type semiconductor layer 1. In the channel region 7, potential barriers PB1 and PB2 are formed to extend from the source layer 2 side to a base BM side of the fin-type semiconductor layer 1.

The gate electrode 4 is composed of sub electrodes 5a and 5b having work functions different from each other. The sub electrode 5a is arranged on the source layer 2 side of the fin-type semiconductor layer 1 to extend toward the drain layer 3 side on the base BM side of the fin-type semiconductor layer 1. The sub electrode 5b is arranged on the drain layer 3 side of the fin-type semiconductor layer 1. At this time, the sub electrode 5a can have a work function higher than the sub electrode 5b to form the potential barriers PB1 and PB2 in the channel region 7.

For example, the sub electrode 5a can have a gate length L1 on the base side of the fin-type semiconductor layer 1 and have a gate length L2 smaller than the gate length L1 above the base side. The sub electrode 5b can have a gate length L3 smaller than the gate length L1 above the base side of the fin-type semiconductor layer 1. The sum of the gate length L2 and the gate length L3 can be the gate length L1.

The sub electrode 5a is formed on both side surfaces of the fin-type semiconductor layer 1 with a gate dielectric film 6a therebetween and the sub electrode 5b is formed on both side surfaces of the fin-type semiconductor layer 1 with a gate dielectric film 6b therebetween. For example, W can be used as the material of the sub electrode 5a and Al can be used as the material of the sub electrode 5b. Alternatively, the material of the sub electrode 5a may be selected, for example, from TaN, Ru, TiAlN, and the like, and the material of the sub electrode 5b may be selected, for example, from HfN, NiSi, Mo, TiN, and the like.

Moreover, the materials of the gate dielectric films 6a and 6b may be different from each other or the same. The materials of the gate dielectric films 6a and 6b can be selected, for example, from SiO₂, HfO, HfSiO, HfSiON, HfAlO, HfAlSiON, La₂O₃, and the like. Moreover, when the potential barriers PB1 and PB2 can be formed in the channel region 7 by making the materials of the gate dielectric films 6a and 6b different from each other, the work functions of the sub electrodes 5a and 5b may be made equal to each other. Moreover, when the potential barriers PB1 and PB2 are formed in the channel region 7, the gate dielectric films 6a and 6b may have film thicknesses different from each other.

In order to suppress variations in electrical characteristics of a field-effect transistor or decrease in mobility due to variations in the impurity concentration in the channel region 7, preferably, the impurity concentration in the channel region 7 is reduced and the channel region 7 is fully depleted. The fin width is preferably made smaller than the gate length to fully deplete the channel region 7.

The potential controllability of the channel region 7 can be improved by providing the gate electrode 4 on both sides of the channel region 7, therefore, it is possible to achieve both a reduction of the short channel effects and an increase of the current driving force.

Moreover, punch-through can be prevented from occurring easily on the bulk side of the fin while enabling the effective gate length to be shortened by forming the potential barriers PB1 and PB2 in the channel region 7, therefore, the current driving force can be further increased and the off-leakage current can be reduced.

### Second Embodiment

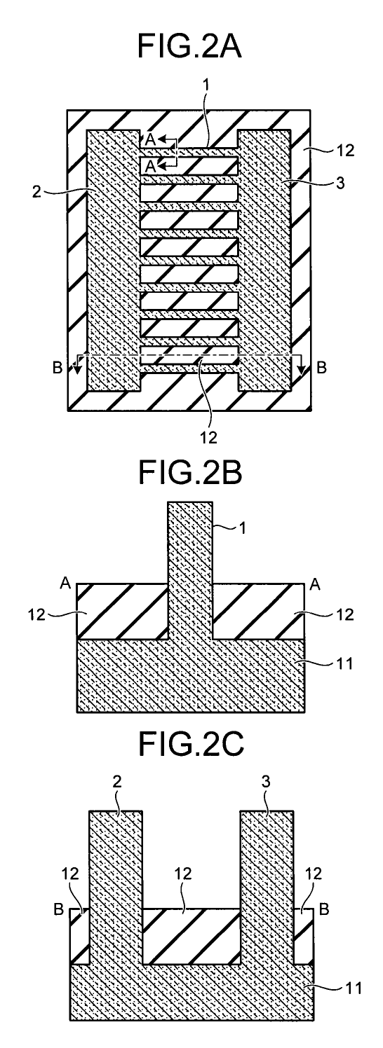

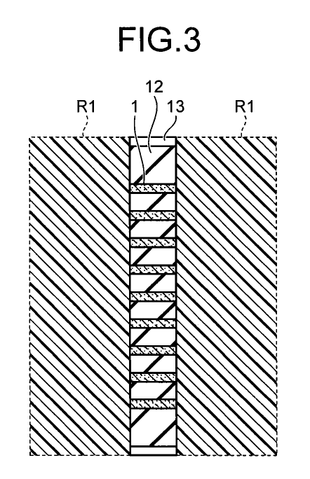

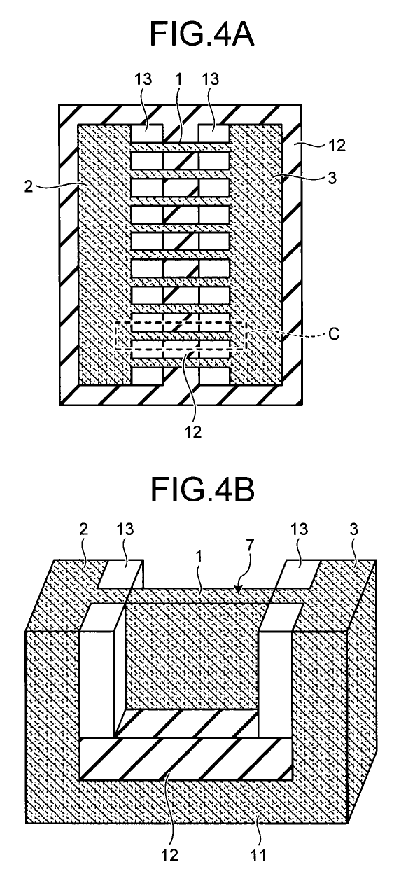

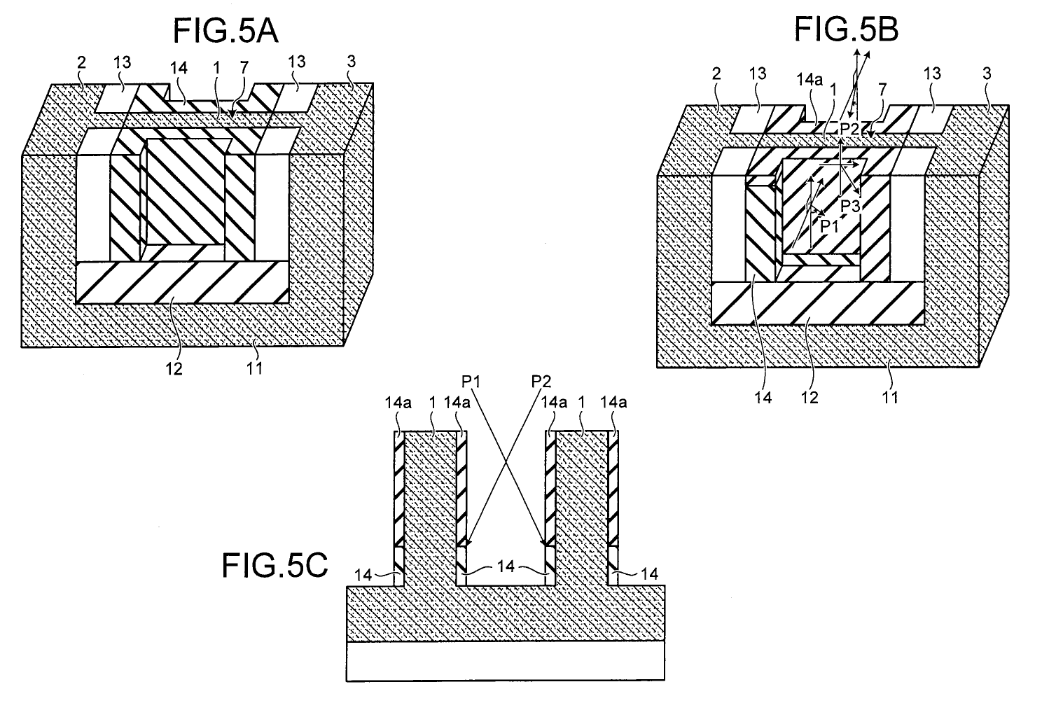

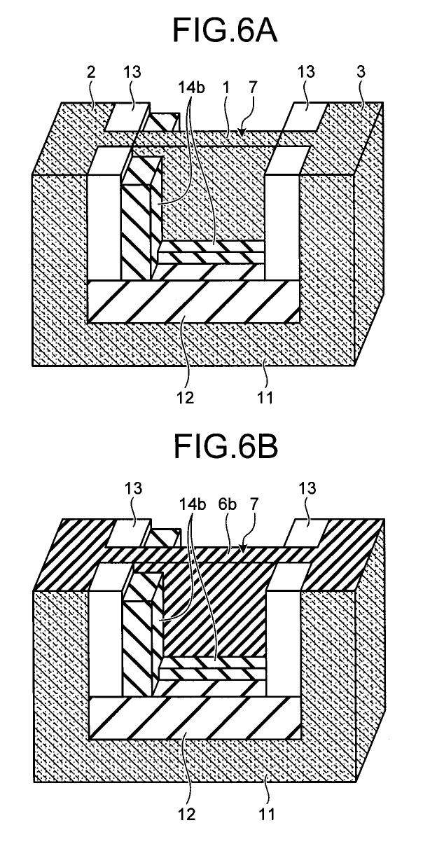

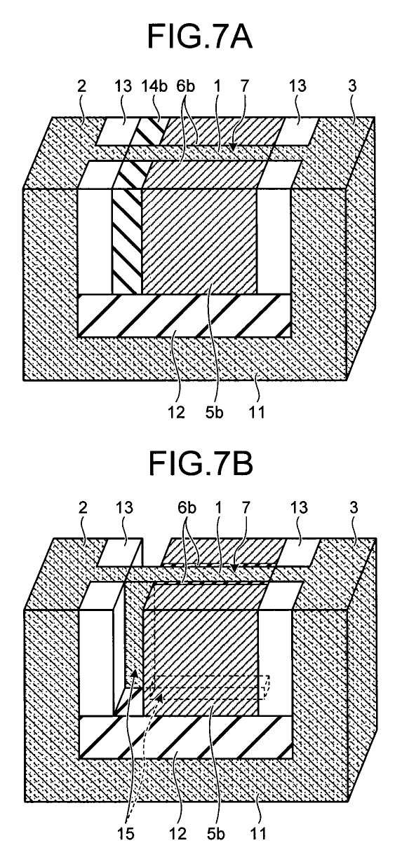

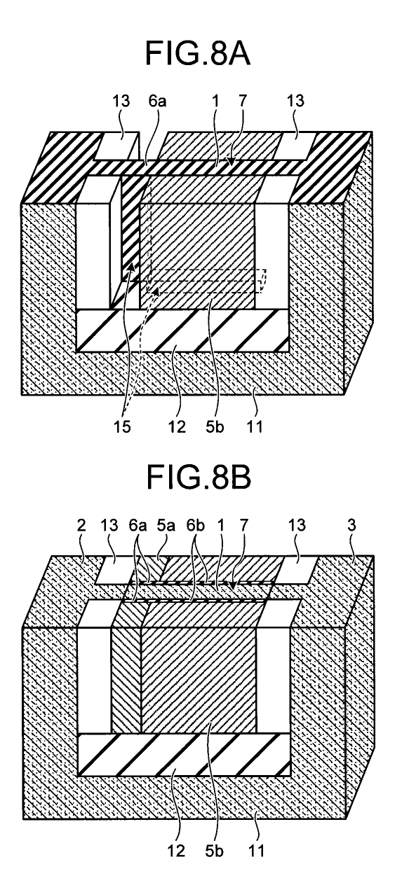

FIG. 2A, FIG. 3, and FIG. 4A are plan views illustrating a manufacturing method of a semiconductor device according to the second embodiment, FIG. 2B is a cross-sectional view illustrating a configuration cut along line A-A in FIG. 2A, FIG. 2C is a cross-sectional view illustrating a configuration cut along line B-B in FIG. 2A, FIG. 4B is a perspective view illustrating a configuration of a portion C in FIG. 4A cut out from the semiconductor device, FIG. 5A, FIG. 5B, FIG. 6A, FIG. 6B, FIG. 7A, FIG. 7B, FIG. 8A, and FIG. 8B are perspective views illustrating the manufacturing method of the semiconductor device according to the second embodiment, and FIG. 5C is a cross-sectional view illustrating the manufacturing method of the semiconductor device according to the second embodiment.

In FIG. 2A to FIG. 2C, the fin-type semiconductor layer 1 is formed on a semiconductor substrate 11 by patterning a surface layer of the semiconductor substrate 11 by using the photolithography technology and the etching technology. Then, an isolation dielectric layer 12 embedded between the fin-type semiconductor layers 1 is formed on the semiconductor substrate 11 by using a method, such as the CVD. Then, a tip TP side of the fin-type semiconductor layer 1 is exposed by thinning the isolation dielectric layer 12. As the material of the isolation dielectric layer 12, for example, SiN can be used.

Next, as shown in FIG. 3, an interlayer dielectric film 13 is formed on the isolation dielectric layer 12 to fill the portions between the fin-type semiconductor layers 1 by using a method, such as the CVD. Then, a resist pattern R1 is formed on the interlayer dielectric film 13 to extend from the source layer 2 and the drain layer 3 to both end portions of the fin-type semiconductor layer 1 by using the photolithography technology. As the material of the interlayer dielectric film 13, for example, SiN can be used.

Next, as shown in FIG. 4A and FIG. 4B, the channel region 7 of the fin-type semiconductor layer 1 is exposed in a state where the interlayer dielectric film 13 is left on the side surfaces of both end portions of the fin-type semiconductor layer 1 by etching the interlayer dielectric film 13 with the resist pattern R1 as a mask.

Next, as shown in FIG. 5A, a sacrificial film 14 embedded between the fin-type semiconductor layers 1 is formed on the isolation dielectric layer 12 by using a method, such as the CVD. Then, the film thickness of the sacrificial film 14 from the side surface of the fin-type semiconductor layer 1 is set such that the central portion is thinner than both end portions of the fin-type semiconductor layer 1 by patterning the sacrificial film 14 by using the photolithography technology and the etching technology. The material of the sacrificial film 14 can be selected to have a greater etch selectivity than the isolation dielectric layer 12 and the interlayer dielectric film 13 and, for example, SiO₂ can be used as the material of the sacrificial film 14.

Next, as shown in FIG. 5B and FIG. 5C, a high-concentration impurity region 14a is formed in the sacrificial film 14 by obliquely ion-implanting an impurity into the sacrificial film 14. This high-concentration impurity region 14a can be formed to extend from the drain layer 3 side to the tip TP side of the fin-type semiconductor layer 1.

In order to selectively form such the high-concentration impurity region 14a in the sacrificial film 14, the shadowing effects of the fin-type semiconductor layer 1 can be used. At this time, oblique ion implantation can be performed a plurality of times at different angles. In other words, an impurity can be effectively injected deeply into the sacrificial film 14 by oblique ion implantations P1 and P2 in a portion of the sacrificial film 14 having a small film thickness from the side surface of the fin-type semiconductor layer 1 compared with a thick portion. At this time, it is possible to cause an impurity not to reach a deepest portion of the sacrificial film 14 in the portion of the sacrificial film 14 having a small film thickness due to the shadowing effects of the fin-type semiconductor layer 1. Moreover, an impurity can be injected into a deepest portion of the sacrificial film 14 on the drain layer 3 side in the portion of the sacrificial film 14 having a large film thickness from the side surface of the fin-type semiconductor layer 1 by an oblique ion implantation P3.

Next, as shown in FIG. 6A, a dummy electrode 14b composed of the sacrificial film 14 is formed by selectively removing the high-concentration impurity region 14a by a method, such as a wet etching. This dummy electrode 14b can be arranged on the source layer 2 side of the fin-type semiconductor layer 1 to extend toward the drain layer 3 side on the base BM side of the fin-type semiconductor layer 1. Moreover, the dummy electrode 14b can be formed such that the width is smaller on the base BM side than the drain layer 3 side of the fin-type semiconductor layer 1.

Next, as shown in FIG. 6B, the gate dielectric film 6b is formed on the side surfaces of the fin-type semiconductor layer 1 exposed from the dummy electrode 14b by using a method, such as the CVD or the thermal oxidation.

Next, as shown in FIG. 7A, the sub electrode 5b arranged on the side surface of the fin-type semiconductor layer 1 on the drain layer 3 side is formed on the gate dielectric film 6b by using a method, such as the CVD. Then, the surface of the dummy electrode 14b is exposed by thinning the sub electrode 5b by a method, such as the CMP.

Next, as shown in FIG. 7B, a gap 15, which is extended toward the drain layer 3 side on the base BM side of the fin-type semiconductor layer 1, is formed on the source layer 2 side of the fin-type semiconductor layer 1 by selectively removing the dummy electrode 14b by a method, such as a wet etching.

Next, as shown in FIG. 8A, the gate dielectric film 6a is formed on the side surfaces of the fin-type semiconductor layer 1 exposed in the gap 15 by using a method, such as the CVD or the thermal oxidation.

Next, as shown in FIG. 8B, the sub electrode 5a embedded in the gap 15 is formed on the gate dielectric film 6a by using a method, such as the CVD or sputtering. Then, the surface of the sub electrode 5b is exposed by thinning the sub electrode 5a by a method, such as the CMP.

The dummy electrode 14b can be arranged on the source layer 2 side of the fin-type semiconductor layer 1 to extend toward the drain layer 3 side on the base BM side of the fin-type semiconductor layer 1 by forming the high-concentration impurity region 14a in the sacrificial film 14 by oblique ion implantation using the shadowing effects of the fin-type semiconductor layer 1. Therefore, the sub electrode 5a can be arranged on the source layer 2 side of the fin-type semiconductor layer 1 to extend toward the drain layer 3 side on the base BM side of the fin-type semiconductor layer 1 by replacing the dummy electrode 14b with the sub electrode 5a, therefore, the off-leakage current can be reduced while increasing the current driving force of the fin transistor.

### Third Embodiment

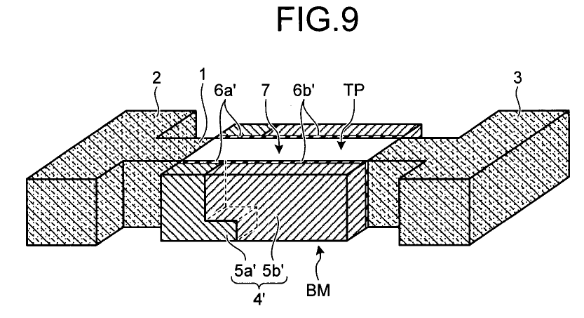

FIG. 9 is a perspective view illustrating a schematic configuration of a semiconductor device according to the third embodiment.

In FIG. 9, in this semiconductor device, a gate electrode 4′ is provided instead of the gate electrode 4 of the semiconductor device in FIG. 1 and gate dielectric films 6a′ and 6b′ are provided instead of the gate dielectric films 6a and 6b. Sub electrodes 5a′ and 5b′ are provided in the gate electrode 4′. The sub electrode 5a′ is arranged on the source layer 2 side of the fin-type semiconductor layer 1 to extend toward the drain layer 3 side on the base BM side of the fin-type semiconductor layer 1. At this time, whereas the sub electrode 5a in FIG. 1 is extended to have a length equal to the gate length on the base BM side of the fin-type semiconductor layer 1, the sub electrode 5a′ in FIG. 9 is extended to have a length shorter than the gate length on the base BM side of the fin-type semiconductor layer 1. The sub electrode 5b′ is arranged on the drain layer 3 side of the fin-type semiconductor layer 1. On the base side of the fin-type semiconductor layer 1, the sub electrode 5b′ is narrowed toward the drain layer 3 side by the extended length of the sub electrode 5a′ toward the drain layer 3 side. The sub electrodes 5a′ and 5b′ can be configured similarly to the sub electrodes 5a and 5b except for the above point.

Then, the sub electrode 5a′ is formed on both side surfaces of the fin-type semiconductor layer 1 with the gate dielectric film 6a′ therebetween and the sub electrode 5b′ is formed on both side surfaces of the fin-type semiconductor layer 1 with the gate dielectric film 6b′ therebetween.

The effective gate width can be increased compared with the semiconductor device in FIG. 1 by shortening the length of the sub electrode 5a′ on the base BM side of the fin-type semiconductor layer 1 compared with the sub electrode 5a, therefore, the current driving force can be increased.

### Fourth Embodiment

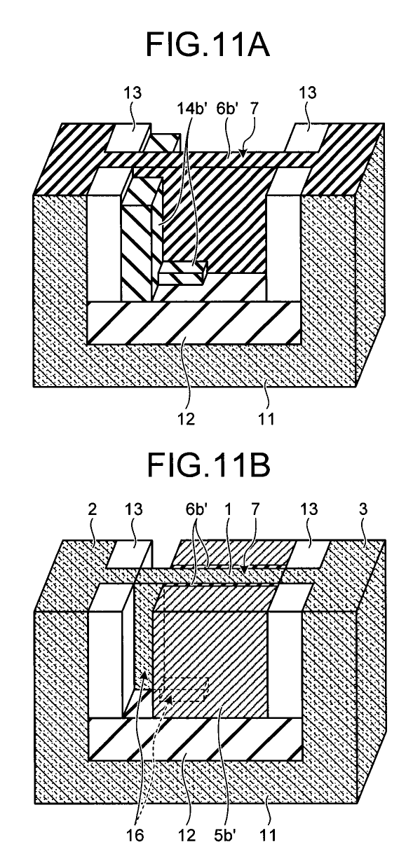

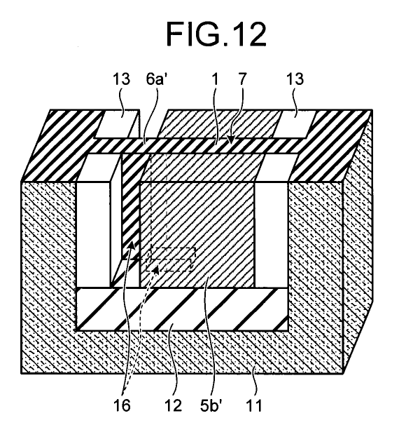

FIG. 10A is a plan view illustrating the manufacturing method of the semiconductor device according to the fourth embodiment, FIG. 10B is a perspective view illustrating a configuration of a portion C′ in FIG. 10A cut out from the semiconductor device, and FIG. 11A, FIG. 11B, and FIG. 12 are perspective views illustrating the manufacturing method of the semiconductor device according to the fourth embodiment.

In FIG. 10A and FIG. 10B, a dummy electrode 14b′ composed of the sacrificial film 14 is formed in a similar manner to the processes in FIG. 2A, FIG. 2B, FIG. 2C, FIG. 3, FIG. 4A, FIG. 4B, FIG. 5A, FIG. 5B, FIG. 5C, and FIG. 6A. This dummy electrode 14b′ can be arranged on the source layer 2 side of the fin-type semiconductor layer 1 to extend toward the drain layer 3 side so that the dummy electrode 14b′ becomes shorter than the gate length on the base BM side of the fin-type semiconductor layer 1. When the dummy electrode 14b′ is formed, the angle in the oblique ion implantations P1 to P3 in FIG. 5B can be changed from the time when the dummy electrode 14 is formed.

Next, as shown in FIG. 11A, a gate dielectric film 6b′ is formed on the side surfaces of the fin-type semiconductor layer 1 exposed from the dummy electrode 14b′ by using a method, such as the CVD or the thermal oxidation.

Next, as shown in FIG. 11B, a sub electrode 5b′ arranged on the side surface of the fin-type semiconductor layer 1 on the drain layer 3 side is formed on the gate dielectric film 6b′ in a similar manner to the process in FIG. 7A. Then, a gap 16, which is extended toward the drain layer 3 side to be shorter than the gate length on the base BM side of the fin-type semiconductor layer 1, is formed on the source layer 2 side of the fin-type semiconductor layer 1 by selectively removing the dummy electrode 14b′ by a method, such as a wet etching.

Next, as shown in FIG. 12, the gate dielectric film 6a′ is formed on the side surfaces of the fin-type semiconductor layer 1 exposed in the gap 16 by using a method, such as the CVD or the thermal oxidation.

Next, in a similar manner to the process in FIG. 8B, the sub electrode 5a′ embedded in the gap 16 is formed on the gate dielectric film 6a′ by using a method, such as the CVD. Then, the surface of the sub electrode 5b′ is exposed by thinning the sub electrode 5a′ by a method, such as the CMP.

### Fifth Embodiment

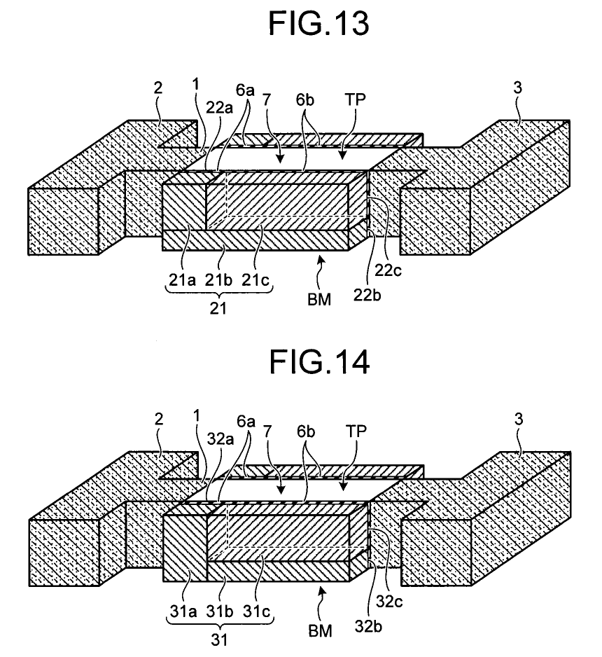

FIG. 13 is a perspective view illustrating the manufacturing method of the semiconductor device according to the fifth embodiment.

In FIG. 13, in this semiconductor device, a gate electrode 21 is provided instead of the gate electrode 4 of the semiconductor device in FIG. 1 and gate dielectric films 22a to 22c are provided instead of the gate dielectric films 6a and 6b. Sub electrodes 21a to 21c are provided in the gate electrode 21. The work functions of the sub electrodes 21a to 21c can be made different from each other. The condition Φa>Φb>Φc or Φb>Φa>Φc can be satisfied, where Φa, Φb, Φc are the work functions of the sub electrodes 21a to 21c, respectively.

The sub electrode 21a is arranged on the source layer 2 side on the tip TP side of the fin-type semiconductor layer 1. The sub electrode 21b is arranged to extend from the source layer 2 side to the drain layer 3 side on the base BM side of the fin-type semiconductor layer 1. The sub electrode 21c is arranged on the drain layer 3 side on the tip TP side of the fin-type semiconductor layer 1.

The sub electrode 21a is formed on both side surfaces of the fin-type semiconductor layer 1 with the gate dielectric film 22a therebetween, the sub electrode 21b is formed on both side surfaces of the fin-type semiconductor layer 1 with the gate dielectric film 22b therebetween, and the sub electrode 21c is formed on both side surfaces of the fin-type semiconductor layer 1 with the gate dielectric film 22c therebetween.

Punch-through can be prevented from occurring easily on the bulk side of the fin while enabling the effective gate length to be shortened by making the work functions of the sub electrodes 21a to 21c different from each other, therefore, the off-leakage current can be reduced while increasing the current driving force.

### Sixth Embodiment

FIG. 14 is a perspective view illustrating the manufacturing method of the semiconductor device according to the sixth embodiment.

In FIG. 14, in this semiconductor device, a gate electrode 31 is provided instead of the gate electrode 4 of the semiconductor device in FIG. 1 and gate dielectric films 32a to 32c are provided instead of the gate dielectric films 6a and 6b. Sub electrodes 31a to 31c are provided in the gate electrode 31. The work functions of the sub electrodes 31a to 31c can be made different from each other. The condition Φa>Φb>Φc or Φb>Φa>Φc can be satisfied, where Φa, Φb, Φc are the work functions of the sub electrodes 31a to 31c, respectively.

The sub electrode 31a is arranged to extend from the tip TP side on the source layer 2 side to the base BM side of the fin-type semiconductor layer 1. The sub electrode 31b is arranged on the drain layer 3 side on the base BM side of the fin-type semiconductor layer 1. The sub electrode 31c is arranged on the drain layer 3 side on the tip TP side of the fin-type semiconductor layer 1.

The sub electrode 31a is formed on both side surfaces of the fin-type semiconductor layer 1 with the gate dielectric film 32a therebetween, the sub electrode 31b is formed on both side surfaces of the fin-type semiconductor layer 1 with the gate dielectric film 32b therebetween, and the sub electrode 31c is formed on both side surfaces of the fin-type semiconductor layer 1 with the gate dielectric film 32c therebetween.

Punch-through can be prevented from occurring easily on the bulk side of the fin while enabling the effective gate length to be shortened by making the work functions of the sub electrodes 31a to 31c different from each other, therefore, the off-leakage current can be reduced while increasing the current driving force.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a fin-type semiconductor layer formed on a semiconductor substrate;
a source layer connected to one end of the fin-type semiconductor layer;
a drain layer connected to the other end of the fin-type semiconductor layer; and
a gate electrode that forms a channel region on a side surface of the fin-type semiconductor layer, wherein
a first potential barrier is formed on the drain layer side and a second potential barrier is formed on a base side of the fin-type semiconductor layer in the channel region.

2. The semiconductor device according to claim 1, wherein
the gate electrode includes
a first sub electrode that is arranged on the source layer side of the fin-type semiconductor layer to extend toward the drain layer side on the base side of the fin-type semiconductor layer and has a first work function, and
a second sub electrode that is arranged on the drain layer side of the fin-type semiconductor layer and has a second work function different from the first work function.

3. The semiconductor device according to claim 2, wherein
the first sub electrode has a first gate length on the base side of the fin-type semiconductor layer and has a second gate length smaller than the first gate length above the base side, and
the second sub electrode has a third gate length smaller than the first gate length above the base side.

4. The semiconductor device according to claim 3, wherein a sum of the second gate length and the third gate length is the first gate length.

5. The semiconductor device according to claim 2, wherein, on the base side of the fin-type semiconductor layer, the second sub electrode is narrowed toward the drain layer side by an extended length of the first sub electrode toward the drain layer side.

6. The semiconductor device according to claim 2, wherein the second sub electrode is formed on a portion of the first sub electrode formed to extend toward the drain layer side.

7. The semiconductor device according to claim 6, wherein the second sub electrode penetrates the first sub electrode to the source layer side on the base side of the fin-type semiconductor layer.

8. The semiconductor device according to claim 6, wherein the second sub electrode is shorter than a gate length of the gate electrode on the base side of the fin-type semiconductor layer.

9. The semiconductor device according to claim 1, wherein the channel region is fully depleted.

10. The semiconductor device according to claim 9, wherein a fin width of the fin-type semiconductor layer is smaller than a gate length.

11. A manufacturing method of a semiconductor device comprising:
forming a fin-type semiconductor layer, which is connected to a source layer at one end and is connected to a drain layer at the other end, on a semiconductor substrate;
forming a dummy electrode on a channel region on a side surface of the fin-type semiconductor layer to extend toward the drain layer side on a base side of the fin-type semiconductor layer;
forming a first gate dielectric film on the channel region exposed from the dummy electrode;
forming a first sub electrode having a first work function on the first gate dielectric film;
removing the dummy electrode after forming the first sub electrode;
forming a second gate dielectric film on a channel region exposed by removing the dummy electrode; and
forming a second sub electrode having a second work function on the second gate dielectric film.

12. The manufacturing method of a semiconductor device according to claim 11, wherein
the forming the dummy electrode on the channel region on the side surface of the fin-type semiconductor layer to extend toward the drain layer side on the base side of the fin-type semiconductor layer includes
forming a sacrificial film on the channel region on the side surface of the fin-type semiconductor layer,
patterning the sacrificial film so that a thickness of the sacrificial film becomes larger on the drain layer side and the source layer side,
performing oblique ion implantation on the sacrificial film after the patterning so that an impurity concentration in the sacrificial film becomes higher in a portion from the drain layer side to the tip side of the fin-type semiconductor layer, and
selectively removing a part of the sacrificial film in which the impurity concentration becomes high.

13. The manufacturing method of a semiconductor device according to claim 12, wherein the dummy electrode is such that a width is smaller on the base side than the drain layer side of the fin-type semiconductor layer.

14. The manufacturing method of a semiconductor device according to claim 13, wherein the first sub electrode covers the dummy electrode on the base side of the fin-type semiconductor layer.

15. The manufacturing method of a semiconductor device according to claim 14, wherein the second sub electrode is embedded under the first sub electrode on the base side of the fin-type semiconductor layer.

16. The manufacturing method of a semiconductor device according to claim 15, wherein the second sub electrode penetrates the first sub electrode to the source layer side on the base side of the fin-type semiconductor layer.

17. The manufacturing method of a semiconductor device according to claim 11, wherein
the first sub electrode has a first gate length on the base side of the fin-type semiconductor layer and has a second gate length smaller than the first gate length above the base side, and
the second sub electrode has a third gate length smaller than the first gate length above the base side.

18. The manufacturing method of a semiconductor device according to claim 11, wherein the second sub electrode is shorter than a gate length of the gate electrode on the base side of the fin-type semiconductor layer.

19. The manufacturing method of a semiconductor device according to claim 11, wherein the channel region is fully depleted.

20. The manufacturing method of a semiconductor device according to claim 19, wherein a fin width of the fin-type semiconductor layer is smaller than a gate length.
